(19) United States
(12) Patent Application Publication
(10) Pub. No.: US 2006/0119414 A1
(43) Pub. Date: Jun. 8, 2006

(54) Gate drive circuit for semiconductor device

(75) Inventors: Shigetada Gotou, Tokyo (JP); Takamasa Asai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: MITSUBISHI DENKI KABUSHIKI KAISHA

(21) Appl. No.: 11/001,001

(22) Filed: Dec. 2, 2004

(51) Int. Cl. H03K 17/687

(52) U.S. Cl. 327/427

(57) ABSTRACT

A gate drive circuit is capable of stabilizing gate drive voltage for a semiconductor device. A voltage build-up power supply circuit is disposed for connection between a battery and a power supply terminal of a gate drive IC. When lowering voltage of the battery, the voltage build-up power supply circuit build up the voltage up to a set value and supplies the gate drive IC side with an output voltage, thus enabling a gate drive voltage to be supplied with a stable voltage. The gate drive circuit further includes a first diode disposed for connection between the voltage build-up power supply circuit and the power supply terminal disposed on the gate drive IC side and a second diode disposed for connection between the battery and the power supply terminal disposed on the gate drive IC side.

### BACKGROUND OF THE INVENTION

1. Field of the Invention

The present invention relates to a gate drive circuit for driving a gate of a semiconductor device.

2. Description of the Related Art

In a conventional semiconductor device, gate drive voltage supplied to a gate drive circuit for a semiconductor device is arranged to depend on a voltage of battery. Since the gate drive voltage for the conventional semiconductor device depends on the voltage of battery, as the reduction of battery voltage, the gate drive voltage reduces in proportion to the battery voltage. Accordingly, a problem exists in that a switching time of the semiconductor device becomes longer, thereby increasing a loss. Moreover, another problem exists in that noise resistance is reduced, thereby increasing a risk of malfunction.

### SUMMARY OF THE INVENTION

The present invention was made to solve the above-discussed problems and has an object of obtaining a gate drive circuit for a semiconductor device, capable of supplying stable voltage to a gate drive IC side and securing stable gate drive voltage.

A gate drive circuit for a semiconductor device according to this invention includes: a battery for supplying power supply voltage, a gate drive IC for driving a gate of the semiconductor device, an power supply terminal disposed on the mentioned gate drive IC side, and a voltage build-up power supply circuit disposed for connection between the mentioned power supply terminal and the mentioned battery for inputting the mentioned power supply voltage and supplying an output voltage not lower than a set value to the mentioned gate drive IC side.

According to the gate drive circuit according to this invention, it is possible to supply a voltage not lower than a certain voltage acting as a power supply for the gate drive IC, prevent increase of switching loss. As a result, to obtain a gate drive circuit with a high noise resistance can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram of a gate drive circuit for a semiconductor according to Embodiment 1 of this invention.

FIG. 2 is a diagram showing input/output characteristics according to Embodiment 1 of the invention.

FIG. 3 is a block diagram of the gate drive circuit for a semiconductor according to Embodiment 2 of the invention.

### DETAILED DESCRIPTION OF THE INVENTION

Embodiment. 1

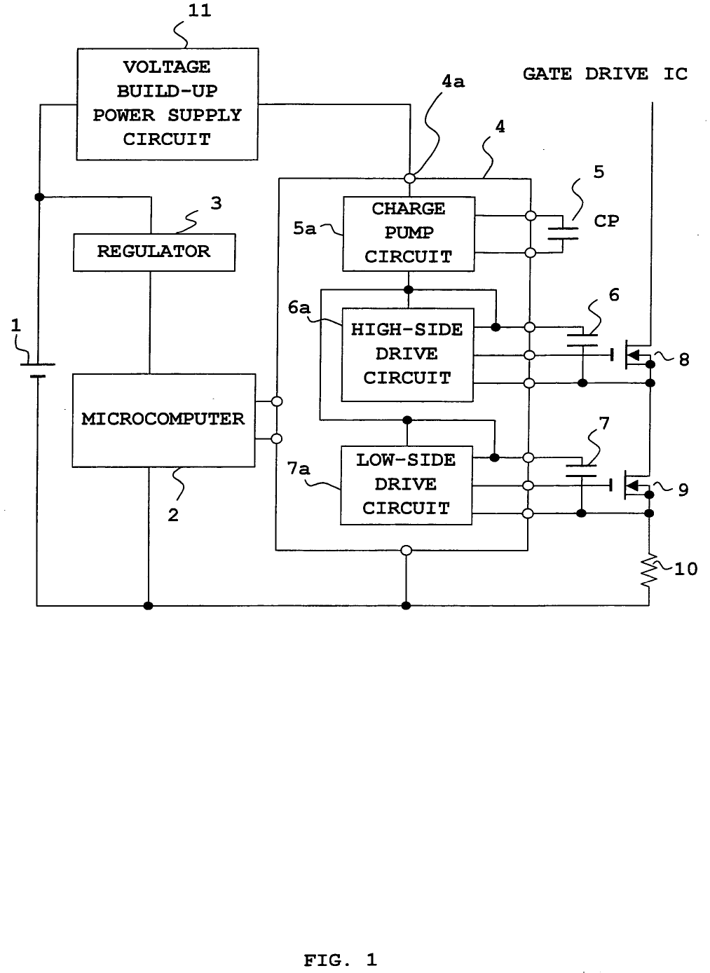

A gate drive circuit for semiconductor device according to Embodiment 1 of the present invention is hereinafter described with reference to FIG. 1. FIG. 1 is a block diagram showing a gate drive circuit for a semiconductor device. As shown in FIG. 1, a voltage build-up power supply circuit 11 is disposed for connection between a battery 1 forming the gate drive circuit and a gate drive IC 4. In this voltage build-up power supply circuit 11, in the case where a supply voltage of the battery 1 acting as an input voltage is lower than a set value, the voltage is built up to the set value. In the case where the voltage is higher than the set value, the voltage is supplied to the gate drive IC 4 side as it is to act as an output voltage. In this manner, the voltage build-up power supply circuit 11 supplies a voltage not lower than a set value at all times.

In this circuit, the battery 1 supplies a power supply voltage and supplies a microcomputer 2, which outputs a gate signal to the gate drive IC 4, with a voltage transformed by a regulator 3 from the output voltage (power supply voltage) of the battery 1, for example, to 5V.

The gate drive IC 4 receives a gate signal from the microcomputer 2, and outputs a voltage inputted from the battery 1 via the voltage build-up power supply circuit 11 after amplifying it up to a voltage necessary for gate drive of the semiconductor device. The gate drive IC 4 is mainly consisted of a charge pump circuit 5a, a high-side drive circuit 6a for driving a high-side semiconductor device 8, a low-side drive circuit 7a for driving a low-side semiconductor device 9.

Further, the gate drive IC 4 inputs the output voltage (power supply voltage) of the battery 1 via a power supply terminal 4a on the gate drive IC side (hereinafter, simply designates as a power supply terminal). Moreover, a capacitor 5 for charge pump, a high-side boot strap capacitor 6 acting as a source of the gate drive voltage for the high-side semiconductor device 8 and a low-side boot strap capacitor 7 acting as a source of gate drive voltage for the low-side semiconductor device 9 are disposed for connection in the gate drive IC 4. A resistor 10 is also disposed for connection to stabilize a GND potential of the low-side semiconductor device 9.

The voltage build-up power supply circuit 11 acts to supply an output voltage equal to a predetermined value (set value or output voltage set value) even in case of variation in input voltage. Accordingly, the gate drive IC 4 can be supplied with a stable voltage regardless of variation in voltage of the battery 1. In addition, the variation in input voltage means that in input voltage is lowered than a required voltage, in which case the voltage build-up power supply circuit 11 acts to build up the output voltage up to a set value and outputs it. On the other hand, in the case where the input voltage is higher than the set value, the voltage build-up power supply circuit 11 does not act but causes the input voltage to bypass and outputs it. As the voltage build-up power supply circuit 11 is a popularly used circuit, the detailed description of inner arrangement thereof is omitted herein.

Now, operations of this gate drive circuit for the semiconductor device are hereinafter described.

A gate drive voltage of the high-side semiconductor device 8 and low-side semiconductor device 9 is supplied from the battery 1 to the gate drive IC via the voltage build-up power supply circuit 11, and is once stored in the capacitor 5 for charge pump via a charge pump circuit 5a. When the low-side semiconductor device 9 is turned ON, the high-side boot strap capacitor 6 is charged with the voltage stored in the capacitor for charge pump 5, which voltage acts as a gate driving power supply (gate drive voltage) for the high-side semiconductor device 8.

The low-side boot strap capacitor 7, which is connected to the GND via the resistor 10, is ready for being charged at all times, and is charged with the voltage stored in the capacitor for charge pump 5, which acts as a gate driving power supply (gate drive voltage) for the low-side semiconductor devise 9.

The fact that the voltage build-up power supply circuit 11 supplies a stable output voltage is already described above. That is, when the output voltage is set to 10V, for example, the voltage build-up power supply circuit 11 supplies 10V as an output voltage even if an input voltage decreases to 6 to 8V.

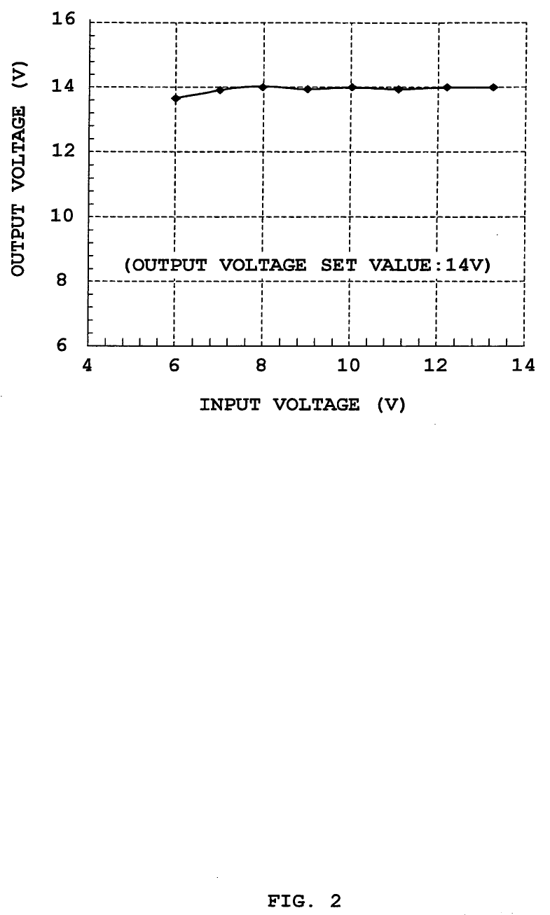

FIG. 2 shows an example of input-output characteristics of the voltage build-up power source circuit 11. As shown in FIG. 2, under the condition that the output voltage set value is set to be 14V, without depending on the variation in input voltage from 6V to 13V, the output voltage is stably kept to about 14V at all times.

In this manner, by interposing the voltage build-up power supply circuit 11 between the battery 1 and the power supply terminal 4a of the gate drive IC 4, a stable and constant voltage outputted via the voltage build-up power source circuit is supplied to the power source terminal 4a of the gate drive IC4. Thus, a stable supply of the gate drive voltage is accomplished.

The semiconductor device tends to be turned ON more exactly when the gate drive voltage is higher, and to be affected more from noises when the gate drive voltage is lower. As described above, however, since a required gate drive voltage is ensured by the insertion of the voltage build-up power supply circuit 11, it is now possible to obtain a gate drive circuit of highly noise resistance in which a semiconductor being in ON state is not erroneously turned to OFF. Furthermore, since a gate drive voltage is stably secured, it takes no much time in switching the semiconductor, thereby preventing increase in switching loss.

Embodiment 2.

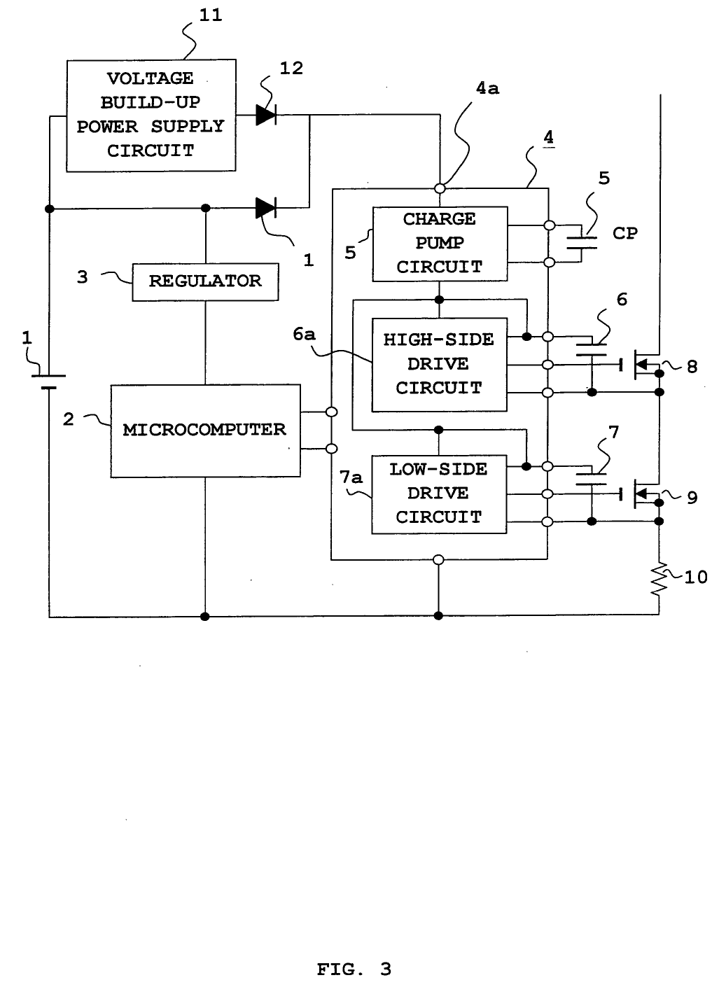

FIG. 3 is a block diagram showing a gate drive circuit according to Embodiment 2 of the invention. In this Embodiment 2, a diode 12 (first diode) is disposed for connection between the voltage build-up power supply circuit 11 and the power supply terminal 4a of the gate drive IC 4, in addition to the arrangement shown in the foregoing Embodiment 1. The diode 12 is connected in such a manner that forward direction extends from the voltage build-up power supply circuit 11 to the power supply terminal 4a. Further, another diode 13 (second diode)is disposed for connection between the battery 1 and the power supply terminal 4a of the gate drive IC 4. The diode 13 is connected in such a manner that forward direction extends from the battery 1 to the power supply terminal 4a is a forward direction of. Thus, a circuit arrangement is established such that either the output voltage of the battery 1 (power supply voltage) or the output voltage of the voltage build-up power supply circuit 11 can be alternatively supplied to the power supply terminal 4a via the diode 12 or via the diode 13.

The diode 12 is a diode for prevention of reverse current and acts to prevent electric current from flowing back to the voltage build-up power supply circuit 11 when an output voltage of the battery 1 is higher than that of the voltage build-up power supply circuit 11 (equal to an output voltage set value). Likewise, the diode 13 is a diode for prevention of reverse current and acts to prevent electric current from flowing back to the battery 1 when an output voltage of the voltage build-up power supply circuit 11 is higher than that of the battery 1.

In the case where an output voltage of the battery 1 is higher than the set value of the voltage build-up power supply circuit 11, the output voltage of the battery 1 is supplied to the power supply terminal 4a of the gate drive IC 4 not via the diode 13 but bypassing the voltage build-up power supply circuit 11.

By using a gate drive circuit of above arrangement, it is possible to supply the power supply terminal 4a on the gate drive IC 4 side with voltage from the battery 1 via the diode 13 in the case of the output voltage of the battery 1 being normal (larger than a value of needed voltage), and from the voltage build-up power supply circuit 11 via the diode 12 in the case of the output voltage of the battery 1 being lower than the output voltage of the voltage build-up power supply circuit 11.

Since a voltage of the battery 1 is normally 12V, the output voltage set value of the voltage build-up power supply circuit 11 is set to about 10V for the use under such a voltage condition.

In addition, the diode 12 and the diode 13 can be arranged employing the same diode. Specifically, MI1A3 produced by SANKEN ELECTRIC CO., LTD. (Schottky Barrier Diode, 30V, 1A) may be preferably used.

Thus, a gate drive circuit according to the invention is arranged in such manner that the gate drive IC 4 side is supplied with power from the battery 1 normally, and the voltage build-up power supply circuit 11 is activated only at the time of the voltage of the battery 1 being lower than the output voltage of the voltage build-up power supply circuit 11. As a result, power consumption of the whole gate drive circuit of the semiconductor device can be economically reduced.

While the presently preferred embodiments of the present invention have been shown and described. It is to be understood that these disclosures are for the purpose of illustration and that various changes and modifications may be made without departing from the scope of the invention as set forth in the appended claims.

What is claimed is:

1. A gate drive circuit for a semiconductor device comprising:
a battery for supplying power supply voltage;
a gate drive IC for driving a gate of the semiconductor device;
an power supply terminal disposed on said gate drive IC side; and
a voltage build-up power supply circuit disposed for connection between said power supply terminal and said battery for inputting said power supply voltage and supplying an output voltage not lower than a set value to said gate drive IC side.

2. The gate drive circuit for a semiconductor device according to claim 1, further comprising;
a first diode connectedly disposed between said voltage build-up power supply circuit and said power supply terminal disposed on said gate drive IC side; and
a second diode disposed for connection between said battery and said power supply terminal disposed on said gate drive IC side,
wherein said power supply terminal is supplied with voltage via said first diode or said second diode.

3. The gate drive circuit for a semiconductor device according to claim 1, further comprising;
a first diode connectedly disposed between said voltage build-up power supply circuit and said power supply terminal disposed on said gate drive IC side, and of which forward direction extends from the voltage build-up power supply circuit to the power supply terminal; and
a second diode disposed for connection between said battery and said power supply terminal disposed on said gate drive IC side, and of which forward direction extends from said battery to said power supply terminal;
wherein said power supply terminal is supplied with voltage via said first diode or said second diode.
